(19) United States
(12) Patent Application Publication
(10) Pub. No.: US 2024/0413049 A1
(43) Pub. Date: Dec. 12, 2024

(54) SEMICONDUCTOR DEVICE

(71) Applicant: Rohm Co., Ltd., Kyoto-shi (JP)

(72) Inventors: Kazunori FUJI, Kyoto-shi (JP); Natsuya YOSHIDA, Kyoto-shi (JP); Yo MOCHIZUKI, Kyoto-shi (JP)

(21) Appl. No.: 18/805,794

(22) Filed: Aug. 15, 2024

Related U.S. Application Data
(63) Continuation of application No. PCT/JP2023/004370, filed on Feb. 9, 2023.

(30) Foreign Application Priority Data
Feb. 24, 2022 (JP) 2022-027130

(51) Int. Cl. H01L 23/373; H01L 23/00; H01L 23/31; H01L 23/538; H01L 25/065

(52) U.S. Cl. CPC H01L 23/3736; H01L 24/80; H01L 25/0655; H01L 23/3107; H01L 23/538; H01L 24/32; H01L 2224/32227; H01L 2224/8083

(57) ABSTRACT

A semiconductor device includes a first semiconductor element, a sealing resin, and a heat dissipating layer. The first semiconductor element includes a first obverse surface that faces in a first direction, and a first electrode and a second electrode that are located on a side opposite the first obverse surface in the first direction. The sealing resin covers the first semiconductor element. The heat dissipating layer is bonded to the first obverse surface. The heat dissipating layer includes a heat dissipating surface facing a same side as the first obverse surface in the first direction. The heat dissipating surface is exposed from the sealing resin to the outside. As viewed in the first direction, the peripheral edge of the heat dissipating surface surrounds the first obverse surface.

### TECHNICAL FIELD

The present disclosure relates to semiconductor devices.

### BACKGROUND ART

JP-A-2020-188085 discloses an example of a semiconductor device that is provided with a lateral semiconductor element (HEMT). The semiconductor element includes a first electrode and a second electrode. In the semiconductor device, the semiconductor element is bonded to a die pad. The first electrode and the second electrode are electrically connected via wires to a plurality of terminal leads located around the die pad.

To reduce the parasitic inductance of the semiconductor device of JP-A-2020-188085, the first electrode and the second electrode may be electrically connected to a substrate, such as a wiring substrate, by flip-chip mounting the semiconductor element. In this case, the semiconductor element is not bonded to the die pad, so that heat generated by the semiconductor element is conducted to the sealing resin that covers the semiconductor element. The thermal conductivity of the sealing resin is generally lower than that of the die pad. Consequently, semiconductor devices with flip-chip mounted semiconductor elements typically exhibit lower heat dissipation.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with a sealing resin omitted.

FIG. 3 is a plan view corresponding to FIG. 2, with a first semiconductor element, a second semiconductor element, and an IC omitted.

FIG. 4 is a bottom view of the semiconductor device shown in FIG. 1.

FIG. 5 is a sectional view taken along line V-V in FIG. 2.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is an enlarged fragmentary view of FIG. 5, showing a portion around the first semiconductor element and a heat dissipating layer.

FIG. 10 is an enlarged fragmentary view of FIG. 5, showing a portion around the second semiconductor element and the heat dissipating layer.

FIG. 11 is an enlarged fragmentary view of FIG. 7.

FIG. 12 is an enlarged fragmentary view of FIG. 10.

FIG. 13 is a plan view of an enlarged fragmentary sectional view of a semiconductor device according to a variation of the first embodiment of the present disclosure.

FIG. 14 is an enlarged fragmentary sectional view of a semiconductor device according to a second embodiment of the present disclosure, showing a portion around a first semiconductor element and a heat dissipating layer.

FIG. 15 is an enlarged fragmentary sectional view of the semiconductor device shown in FIG. 14, showing a portion around a second semiconductor element and the heat dissipating layer.

FIG. 16 is an enlarged fragmentary view of FIG. 14.

FIG. 17 is a plan view of a semiconductor device according to a third embodiment of the present disclosure.

FIG. 18 is a sectional view taken along line XVIII-XVIII in FIG. 17.

FIG. 19 is a sectional view taken along line XIX-XIX in FIG. 17.

FIG. 20 is an enlarged fragmentary view of FIG. 18.

FIG. 21 is a sectional view of a semiconductor device according to a first variation of the third embodiment of the present disclosure.

FIG. 22 is an enlarged fragmentary view of FIG. 21.

FIG. 23 is a sectional view of a semiconductor device according to a second variation of the third embodiment of the present disclosure.

FIG. 24 is an enlarged fragmentary view of FIG. 23.

FIG. 25 is a plan view of a semiconductor device according to a fourth embodiment of the present disclosure.

FIG. 26 is a sectional view taken along line XXVI-XXVI in FIG. 25.

### DETAILED DESCRIPTION OF EMBODIMENTS

The following describes embodiments of the present disclosure with reference to the accompanying drawings.

### First Embodiment

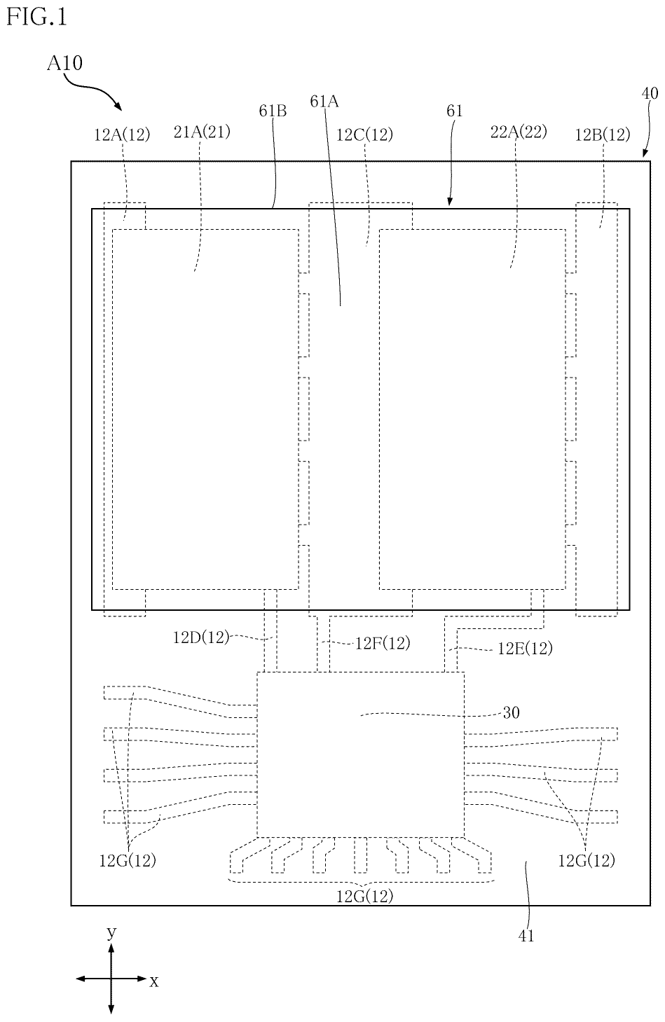

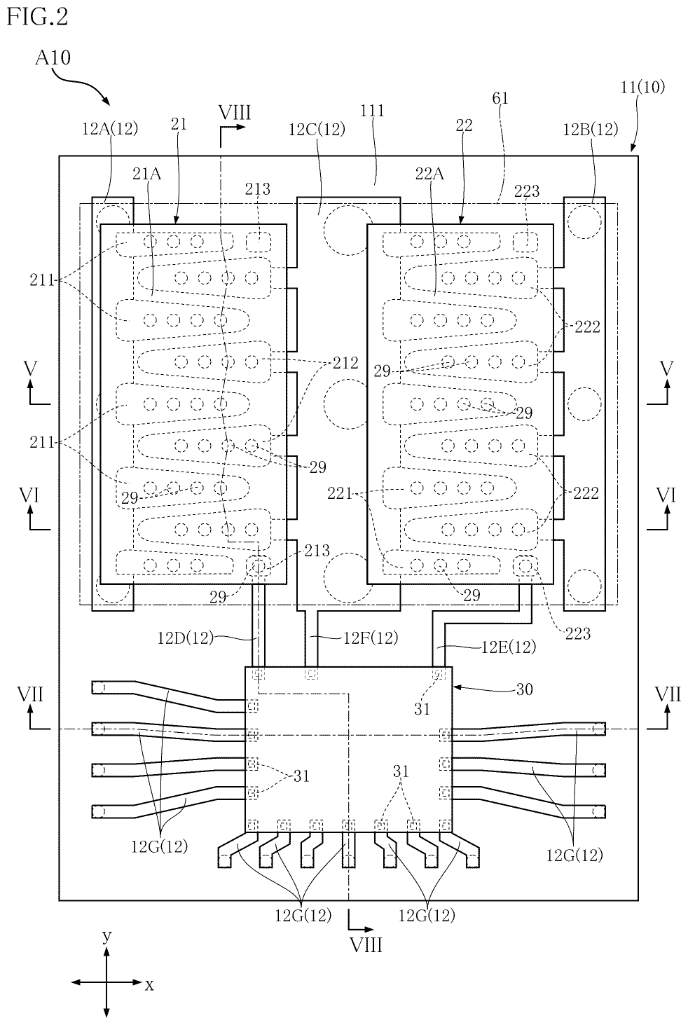

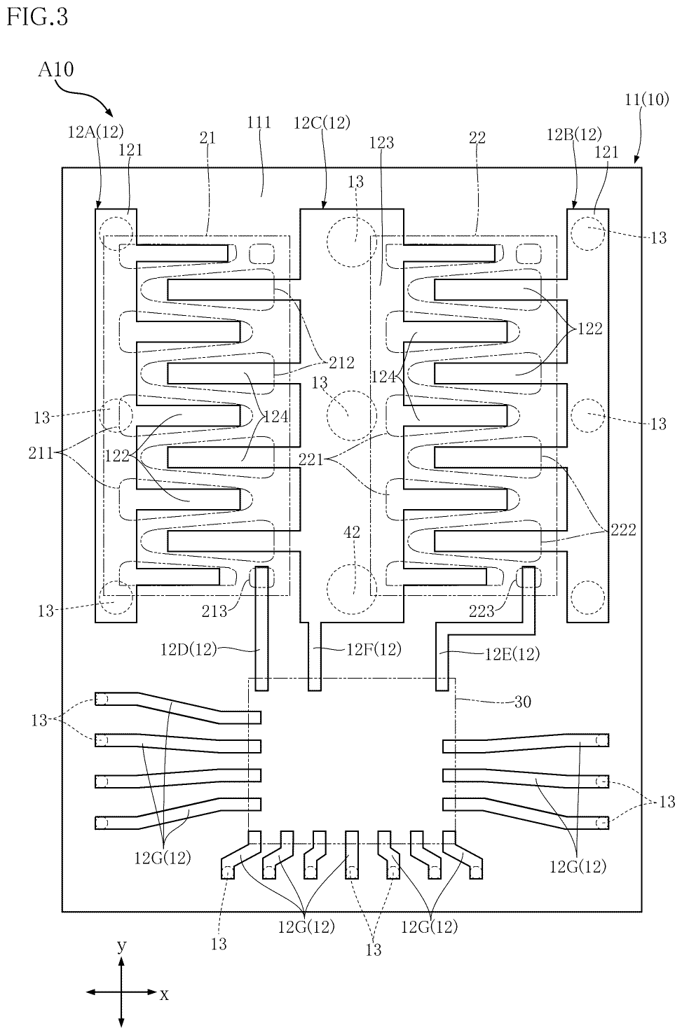

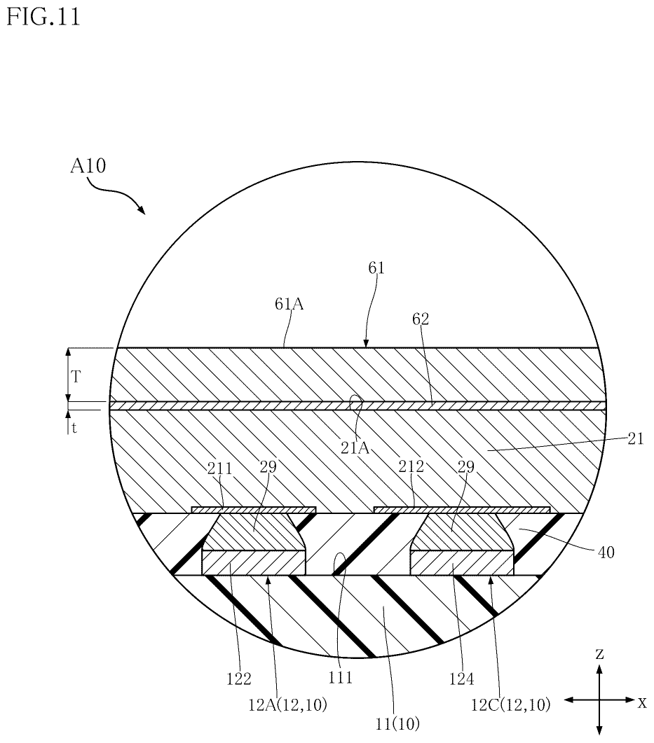

With reference to FIGS. 1 to 12, a semiconductor device A10 according to a first embodiment of the present disclosure is described. The semiconductor device A10 includes a supporting member 10, a first semiconductor element 21, a second semiconductor element 22, a joint layer 29, an IC 30, a sealing resin 40, a plurality of terminals 50, a heat dissipating layer 61, and a first intermediate layer 62. The semiconductor device A10 is packaged in resin for surface mounting on a wiring board. The semiconductor device A10 converts externally supplied DC power into AC power using the first semiconductor element 21 and the second semiconductor element 22. The resulting AC power is supplied to a driving target, such as a motor. For the convenience of illustration, FIG. 2 omits the sealing resin 40. Additionally, FIG. 3 shows a view similar to FIG. 2, with the first semiconductor element 21, the second semiconductor element 22, and IC 30 shown as transparent. In FIG. 3, the first semiconductor element 21, the second semiconductor element 22, and IC 30 are represented by imaginary lines (dotted lines).

In the description of the semiconductor device A10, the direction normal to a mounting surface 111 of a substrate 11, which will be described later, is referred to as the “first direction z”. A direction orthogonal to the first direction z is referred to as the “second direction x”. The direction orthogonal to the first direction z and the second direction x is referred to as the “third direction y”. As shown in FIG. 1, the semiconductor device A10 is rectangular as viewed in the first direction z.

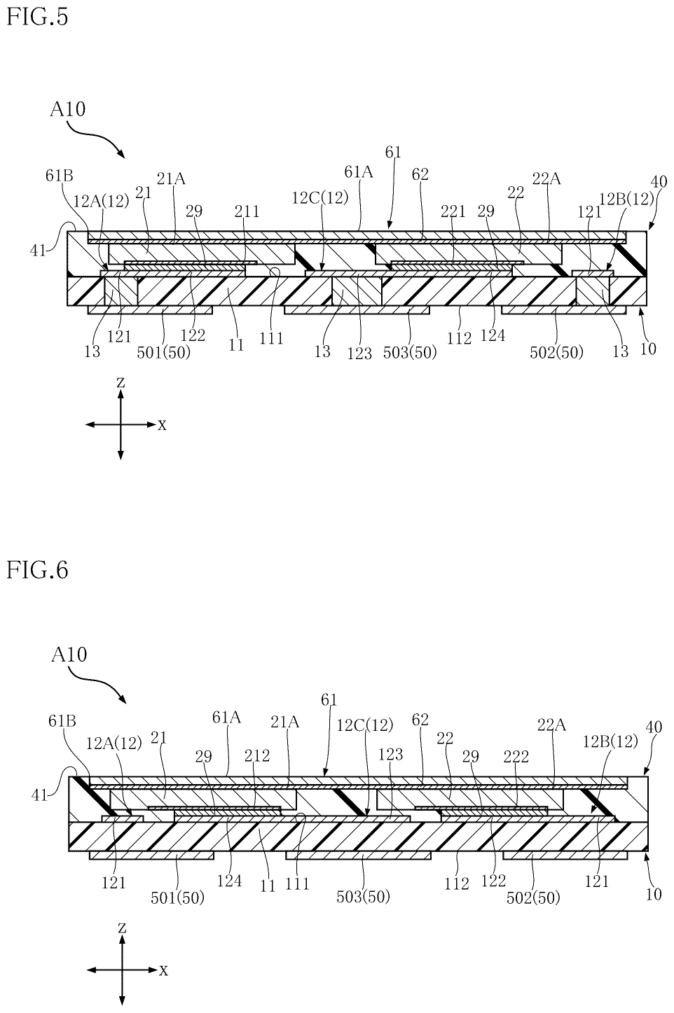

As shown in FIGS. 5 to 8, the supporting member 10 supports the first semiconductor element 21, the second semiconductor element 22, and the sealing resin 40 and also forms conductive paths connecting the first semiconductor element 21, the second semiconductor element 22, and the IC 30 to the wiring board on which the semiconductor device A10 is mounted. The supporting member 10 includes a substrate 11, a plurality of wirings 12, and a plurality of connecting wirings 13. Alternatively, the supporting member 10 may be composed of a plurality of metal conductors (such as leads). In this example, however, the supporting member 10 does not include a die pad for bonding a first obverse surface 21A of the first semiconductor element 21, which will be described later.

As shown in FIGS. 2 to 4, the substrate 11 supports the wirings 12, the connecting wirings 13, and the terminals 50. The substrate 11 is electrically insulating. The substrate 11 is made of a material containing a resin. Examples of such a resin include an epoxy resin.

As shown in FIGS. 5 to 8, the substrate 11 has a mounting surface 111 and a reverse surface 112. The mounting surface 111 faces in the first direction z, and the reverse surface 112 faces away from the mounting surface 111 in the first direction z. The reverse surface 112 is exposed to the outside. When the semiconductor device A10 is mounted on the wiring substrate, the reverse surface 112 faces the wiring substrate.

As shown in FIGS. 5, 6 and 8, the first semiconductor element 21 faces the mounting surface 111 of the substrate 11. The first semiconductor element 21 is a transistor (switching element) mainly used for power conversion. The first semiconductor element 21 is made of a material containing a nitride semiconductor. In the semiconductor device A10, the first semiconductor element 21 is a high electron mobility transistor (HEMT) that is made of a material containing gallium nitride (GaN).

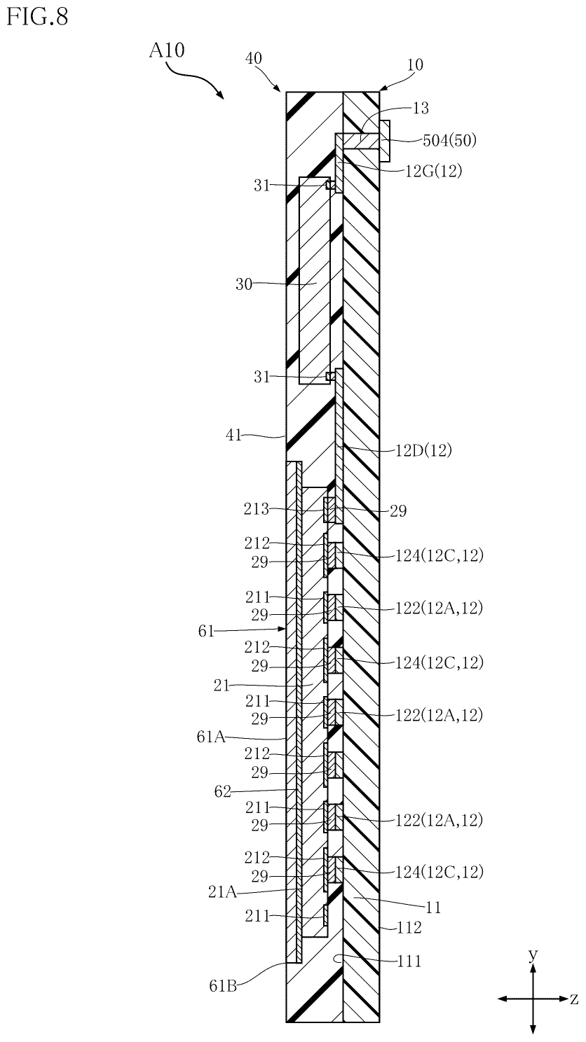

As shown in FIGS. 2 and 8, the first semiconductor element 21 includes a first obverse surface 21A, a plurality of first electrodes 211, a plurality of second electrodes 212, and two first gate electrodes 213. The first obverse surface 21A faces the same side as the mounting surface 111 of the substrate 11 in the first direction z. The first electrodes 211, the second electrodes 212, and the first gate electrodes 213 are located on the side opposite the first obverse surface 21A in the first direction z. Hence, the first electrodes 211, the second electrodes 212, and the first gate electrodes 213 face the mounting surface 111.

As shown in FIG. 2, the first electrodes 211 and the second electrodes 212 extend in the second direction x. The first electrodes 211 and the second electrodes 212 are alternately arranged in the third direction y. The first electrodes 211 conduct electric current proportional to the power to be converted by the first semiconductor element 21. That is, the first electrodes 211 serve as the drains of the first semiconductor element 21. The second electrodes 212 conduct electric current proportional to the power converted by the first semiconductor element 21. That is, the second electrodes 212 serve as the sources of the first semiconductor element 21.

As shown in FIG. 2, the two first gate electrodes 213 on the first semiconductor element 21 are located on opposite sides in the third direction y. One of the two first gate electrodes 213 receives the gate voltage applied for driving the first semiconductor element 21. As viewed in the first direction z, the two first gate electrodes 213 have smaller areas than the first electrodes 211 and the second electrodes 212. The shapes and arrangements of the first electrodes 211, the second electrodes 212, and the first gate electrodes 213 of the first semiconductor element 21 are provided as examples and are not limiting.

As shown in FIGS. 5 and 6, the second semiconductor element 22 faces the mounting surface 111 of the substrate 11. The second semiconductor element 22 is spaced apart from the first semiconductor element 21 in the second direction x. The second semiconductor element 22 is identical to the first semiconductor element 21 in configuration and function. In the description of the second semiconductor element 22 below, overlapping explanations from the description of the first semiconductor element 21 are omitted.

As shown in FIGS. 2, 5 and 6, the second semiconductor element 22 includes a second obverse surface 22A, a plurality of third electrodes 221, a plurality of fourth electrodes 222, and two second gate electrodes 223. The second obverse surface 22A faces the same side as the mounting surface 111 of the substrate 11 in the first direction z. The third electrodes 221, the fourth electrodes 222, and the second gate electrodes 223 are located on the side opposite the second obverse surface 22A in the first direction z. Hence, the third electrodes 221, the fourth electrodes 222, and the second gate electrodes 223 face the mounting surface 111.

The third electrodes 221 are equivalent to the first electrodes 211 of the first semiconductor element 21 in configuration and function. The fourth electrodes 222 are equivalent to the second electrodes 212 of the first semiconductor element 21 in configuration and function. The second gate electrodes 223 are equivalent to the first gate electrodes 213 of the first semiconductor element 21 in configuration and function. Similarly to the description of the first semiconductor 21, element the shapes and configurations of the third electrodes 221, the fourth electrodes 222, and the second gate electrodes 223 of the second semiconductor element 22 are provided as examples and are not limiting.

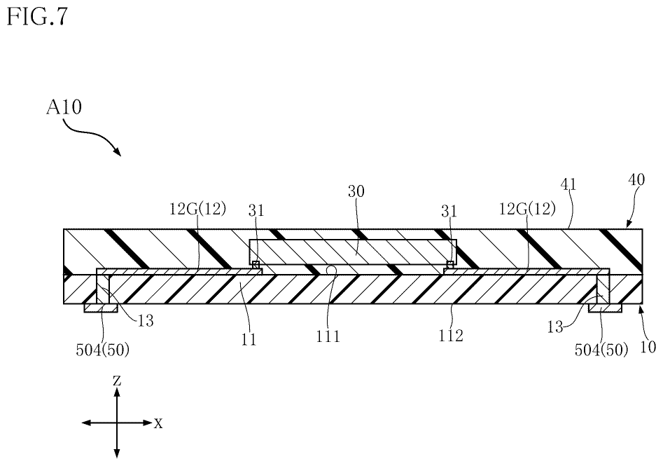

As shown in FIGS. 2 and 7, the IC 30 faces the mounting surface 111 of the substrate 11. The IC 30 is a gate driver that applies the gate voltage between one of the two first gate electrodes 213 of the first semiconductor element 21 and one of the two second gate electrodes 223 of the second semiconductor element 22. The IC 30 includes a plurality of electrodes 31. The electrodes 31 face the mounting surface 111.

As shown in FIGS. 3 and 5 to 8, the wirings 12 are disposed on the mounting surface 111 of the substrate 11. The composition of the wirings 12 includes copper (Cu), for example. The wirings 12, together with the connecting wirings 13 and the terminals 50, form a conductive path between each element 21, of the first semiconductor the second semiconductor element 22, and the IC 30 and the wiring board on which the semiconductor device A10 is mounted.

As shown in FIG. 3, the wirings 12 include an input wiring 12A, a ground wiring 12B, an output wiring 12C, a first gate wiring 12D, a second gate wiring 12E, a potential wiring 12F, and a plurality of control wirings 12G.

As shown in FIG. 3, the input wiring 12A and the ground wiring 12B are spaced apart from each other in the second direction x. Each of the input wiring 12A and the ground wiring 12B includes a first base portion 121 and a plurality of first extending portion 122. The first base portion 121 extends in the third direction y. The first extending portions 122 extend from the first base portion 121 in the second direction x toward a second base portion 123 of the output wiring 12C, which will be described later. The first extending portions 122 are arranged along the third direction y.

As shown in FIG. 5, the first electrodes 211 of the first semiconductor element 21 are electrically connected to the respective first extending portions 122 of the input wiring 12A each via a joint layer 29. As shown in FIG. 6, the fourth electrodes 222 of the second semiconductor element 22 are electrically bonded to the respective first extending portions 122 of the ground wiring 12B each via a joint layer 29. The joint layers 29 are layers of solder, for example. In another example, the joint layers 29 may be solder balls each composed of a metal core surrounded by a tin layer. The material of the joint layers 29 is not limited to these.

As shown in FIG. 3, the output wiring 12C is located between the first base portion 121 of the input wiring 12A and the first base portion 121 of the ground wiring 12B in the second direction x. The output wiring 12C includes a second base portion 123 and a plurality of second extending portions 124. The second base portion 123 extends in the third direction y. The second extending portions 124 extend in the second direction x from either side of the second base portion 123 in the second direction x, toward either the first base portion 121 of the input wiring 12A or toward the first base portion 121 of the ground wiring 12B. The second extending portions 124 are arranged along the third direction y.

As shown in FIG. 6, the second electrodes 212 of the first semiconductor element 21 are electrically bonded to the relevant second extending portions 124 of the output wiring 12C each via a joint layer 29. As shown in FIG. 5, the third electrodes 221 of the second semiconductor element 22 are electrically bonded to the relevant second extending portions 124 of the output wiring 12C each via a joint layer 29. Hence, the third electrodes 221 of the second semiconductor element 22 are electrically connected to the second electrodes 212 of the first semiconductor element 21.

As shown in FIG. 8, one of the two first gate electrodes 213 of the first semiconductor element 21 is electrically bonded to the first gate wiring 12D via a joint layer 29. As shown in FIG. 2, one of the two second gate electrodes 223 of the second semiconductor element 22 is electrically bonded to the second gate wiring 12E via a joint layer 29.

As shown in FIGS. 2 and 3, the potential wiring 12F is connected to the second base portion 123 of the output wiring 12C. The potential wiring 12F is used by the IC 30 to ground the gate voltage applied to one of the two first gate electrodes 213 of the first semiconductor element 21.

As shown in FIGS. 2, 7 and 8, each electrode 31 of the IC 30 is electrically bonded to one of the first gate wiring 12D, the second gate wiring 12E, the potential wiring 12F, and the control wirings 12G. Hence, the IC 30 is electrically connected to one of the two first gate electrodes 213 of the first semiconductor element 21, one of the two second gate electrodes 223 of the second semiconductor element 22, and the output wiring 12C.

As shown in FIGS. 5 and 7, the connecting wirings 13 are embedded in the substrate 11. Both ends of each connecting wiring 13 in the first direction z are exposed at the mounting surface 111 and the reverse surface 112 of the substrate 11. Each connecting wiring 13 is connected to one of the wirings 12, excluding the first gate wiring 12D, the second gate wiring 12E, and the potential wiring 12F. Each connecting wiring 13 is also connected to one of the terminals 50. Hence, each terminal 50 is electrically connected to one of the input wiring 12A, the ground wiring 12B, the output wiring 12C, and the control wirings 12G, out of the plurality of wirings 12. The composition of the connecting wirings 13 includes copper, for example.

As shown in FIGS. 1 and 5 to 8, the sealing resin 40 covers the first semiconductor element 21, the second semiconductor element 22, the IC 30, and the wirings 12. The sealing resin 40 is electrically insulating. The sealing resin 40 is made of a material containing a black epoxy resin, for example. As shown in FIGS. 1 and 5 to 8, the sealing resin 40 has a top surface 41. The top surface 41 faces the same side as the mounting surface 111 of the substrate 11 in the first direction z.

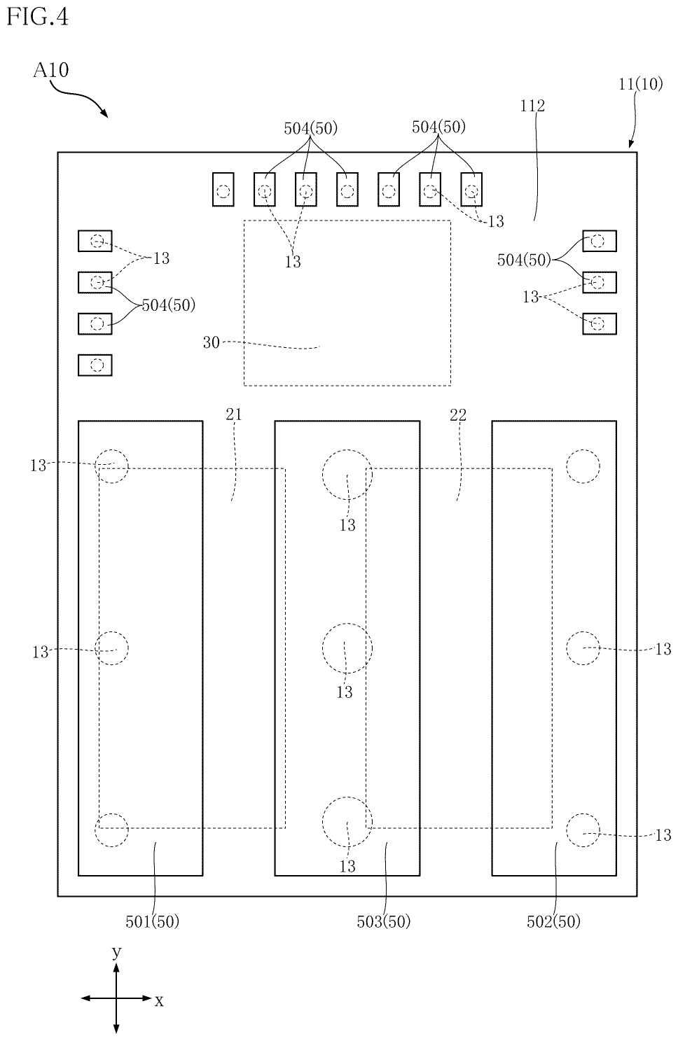

As shown in FIGS. 4 to 8, the terminals 50 are disposed on the reverse surface 112 of the substrate 11. The terminals 50 are electrically connected to a wiring board by soldering. In this way, the semiconductor device A10 is mounted on the wiring board. Each terminal 50 includes a plurality of metal layers. The metal layers may be a nickel layer and a gold (Au) layer that are stacked in the stated order of from the side closer to the reverse surface 112. Alternatively, the metal layers may be a nickel layer, a palladium (Pd) layer, and a gold layer that stacked in the stated order from the side near the reverse surface 112.

As shown in FIG. 4, the terminals 50 include an input terminal 501, a ground terminal 502, an output terminal 503, and a plurality of control terminals 504.

The input terminal 501 is electrically connected to the input wiring 12A. The ground terminal 502 is electrically connected to the ground wiring 12B. The input terminal 501 and the ground terminal 502 receive DC power that is to be converted by the first semiconductor element 21 and the second semiconductor element 22. The input terminal 501 is a positive terminal (P terminal), and the ground terminal 502 is a negative terminal (N terminal).

The output terminal 503 is electrically connected to the output wiring 12C. The output terminal 503 outputs the AC power that is converted by the first semiconductor element 21 and the second semiconductor element 22.

The control terminals 504 are electrically connected to the IC 30 each via a control wiring 12G. One of the control terminals 504 receives power inputted for driving the IC 30. One of the control terminals 504 receives an electrical signal directed to the IC 30. One of the control terminals 504 outputs an electrical signal received from the IC 30.

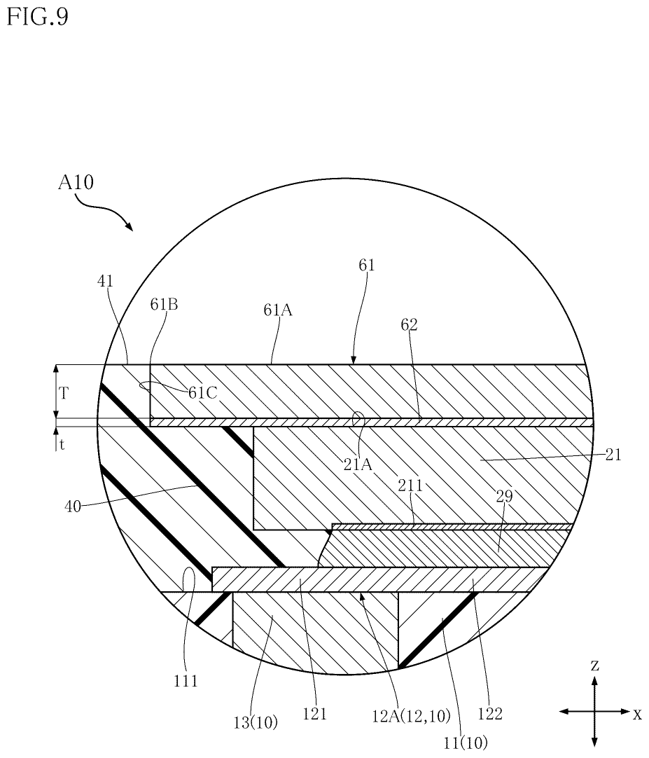

As shown in FIGS. 5, 6 and 8, the heat dissipating layer 61 is bonded to the first obverse surface 21A of the first semiconductor element 21 and the second obverse surface 22A of the second semiconductor element 22. In the semiconductor device A10, the heat dissipating layer 61 is a single conductor. In another example, the heat dissipating layer 61 may be composed of a plurality of conductors stacked in the first direction z. The conductors include metals and graphite. In the semiconductor device A10, the composition of the heat dissipating layer 61 includes copper. As shown in FIG. 9, the heat dissipating layer 61 has a heat dissipating surface 61A, a peripheral edge 61B, and an end surface 61C.

As shown in FIGS. 5, 6 and 8, the heat dissipating surface 61A faces the same side as the first obverse surface 21A of the first semiconductor element 21 in the first direction z. The heat dissipating surface 61A is exposed to the outside from the top surface 41 of the sealing resin 40. The heat dissipating surface 61A is available for attaching a heat sink (not shown), for example. As shown in FIG. 1, the peripheral edge 61B defines the outline of the heat dissipating surface 61A. As viewed in the first direction z, the peripheral edge 61B surrounds the first obverse surface 21A and the second obverse surface 22A of the second semiconductor element 22. As shown in FIG. 9, the end surface 61C faces in a direction orthogonal to the first direction z. The end surface 61C is connected to the heat dissipating surface 61A. The end surface 61C is covered with the sealing resin 40.

As shown in FIGS. 5, 6 and 8, the first intermediate layer 62 is located partly between the first obverse surface 21A of the first semiconductor element 21 and the heat dissipating layer 61, and partly between the second obverse surface 22A of the second semiconductor element 22 and the heat dissipating layer 61. The composition of the first intermediate layer 62 includes aluminum (Al). The first intermediate layer 62 is formed, for example, by sputtering a thin film of metal onto the heat dissipating layer 61.

As shown in FIGS. 9 to 11, the dimension t of the first intermediate layer 62 in the first direction z is smaller than the dimension T of the heat dissipating layer 61 in the first direction z. In addition, the Vickers hardness of the first intermediate layer 62 is lower than that of the heat dissipating layer 61. In the semiconductor device A10, the thermal conductivity of the first intermediate layer 62 is lower than that of the heat dissipating layer 61.

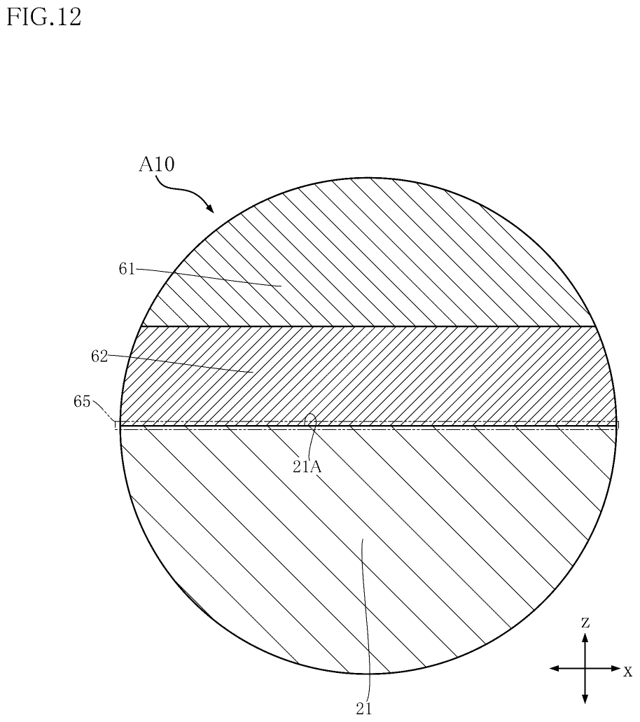

The heat dissipating layer 61 is bonded by solid-phase diffusion to the first obverse surface 21A of the first semiconductor element 21 and the second obverse surface 22A of the second semiconductor element 22 via the first intermediate layer 62. Consequently, as shown in FIG. 12, a solid-phase diffusion bonding layer 69 is present between the first obverse surface 21A and the heat dissipating layer 61. Although not illustrated in the figures, the solid-phase diffusion bonding layer 69 is also present between the second obverse surface 22A and the heat dissipating layer 61. In the semiconductor device A10, the solid-phase diffusion bonding layer 69 is present between the first obverse surface 21A and the first intermediate layer 62, as well as between the second obverse surface 22A and the first intermediate layer 62.

In concept, the solid-phase diffusion bonding layer 69 refers to a metal bonding layer that forms at the interface between two metal layers when the two metal layers in contact with each other are bonded by solid-state diffusion. The solid-phase diffusion bonding layer 69, however, may not be physically present as a metal bonding layer having a sufficient thickness. The solid-phase diffusion bonding layer 69 may be identified as a region where impurities or voids introduced during the solid-state diffusion process persist along the interface of the two metal layers.

### Variation of First Embodiment

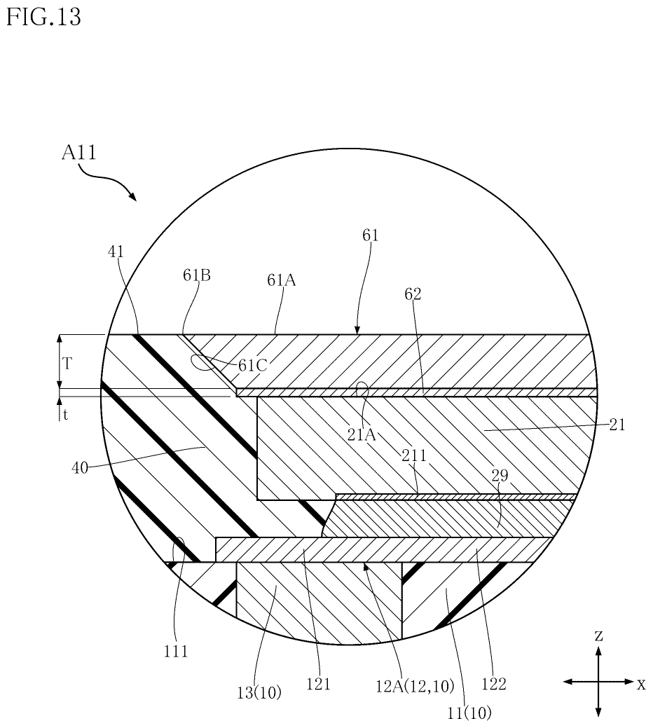

Next, with reference to FIG. 13, the following describes a semiconductor device A11 that is a variation of the semiconductor device A10. The section shown in FIG. 13 is taken along the same position as the section shown in FIG. 9. As shown in FIG. 13, the semiconductor device A11 differs from the semiconductor device A10 in the configuration of the heat dissipating layer 61. The heat dissipating layer 61 of this variation has an end surface 61C that is inclined to be farther away from the first obverse surface 21A of the first semiconductor element 21 as viewed in the first direction z, as the distance from the first obverse surface 21A increases in the first direction z.

Next, the effects of the semiconductor device A10 will be described.

The semiconductor device A10 includes: the first semiconductor element 21 having the first obverse surface 21A facing away from the first and second electrodes 211 and 212 in the first direction z; the sealing resin 40 covering the first semiconductor element 21; and the heat dissipating layer 61 bonded to the first obverse surface 21A. The heat dissipating layer 61 has the heat dissipating surface 61A facing the same side as the first obverse surface 21A in the first direction z and exposed from the sealing resin 40 to the outside. The peripheral edge 61B of the heat dissipating surface 61A surrounds the first obverse surface 21A as viewed in the first direction z. This configuration ensures that heat generated by the first semiconductor element 21 is conducted to the first obverse surface 21A to the heat dissipating layer 61. Supposing that the heat dissipating layer 61 is provided with an imaginary plane extending from the first obverse surface 21A to the heat dissipating surface 61A at an angle of 45° relative to the first obverse surface 21A, the heat conducted to the heat dissipating layer 61 diffuses uniformly in the region surrounded by the imaginary plane. As deduced from this, the configuration of the present embodiment helps reduce the thermal resistance of the heat dissipating layer 61 in the first direction z, allowing heat conducted from the first obverse surface 21A to the heat dissipating layer 61 to reach the heat dissipating surface 61A more quickly. The semiconductor device A10 can therefore improve its heat dissipation.

The solid-phase diffusion bonding layer 69 is present between the first obverse surface 21A of the first semiconductor element 21 and the heat dissipating layer 61. This configuration serves to reduce the thermal resistance between the first obverse surface 21A and the heat dissipating layer 61, compared to, for example, the configuration in which the heat dissipating layer 61 is soldered to the first obverse surface 21A.

The semiconductor device A10 further includes the first intermediate layer 62 between the first obverse surface 21A of the first semiconductor element 21 and the heat dissipating layer 61. The solid-phase diffusion bonding layer 69 is present between the first obverse surface 21A and the first intermediate layer 62. The Vickers hardness of the first layer intermediate 62 is lower than that of the heat dissipating layer 61. This configuration helps reduce the deflection in the first direction z that may occur in each of the heat dissipating layer 61 and the first semiconductor element 21 during the solid-phase diffusion bonding of the heat dissipating layer 61. This is beneficial for achieving a strong bond of the solid-phase diffusion bonding layer 69.

The dimension t of the first intermediate layer 62 in the first direction z is smaller than the dimension T of the heat dissipating layer 61 in the first direction z. In a case where the heat dissipating layer 61 has a higher thermal conductivity than the first intermediate layer 62, this configuration facilitates the heat conduction in a direction orthogonal to the first direction z throughout the heat dissipating layer 61 and the first intermediate layer 62.

In the semiconductor device A11, the end surface 61C of heat dissipating layer 61 is inclined to be farther away from the first obverse surface 21A of the first semiconductor element 21 as viewed in the first direction z, as the distance from the first obverse surface 21A increases in the first direction z. This configuration can reduce the thermal resistance of the heat dissipating layer 61 in the first direction z, while also reducing the volume of the heat dissipating layer 61.

The semiconductor device A10 further includes the terminals 50 that are electrically connected to the wirings 12. The terminals 50 are located on the side opposite the wirings 12 with respect to the substrate 11 in the first direction z. This configuration enables the wirings 12, which are fully covered with the sealing resin 40, to form conductive paths to the wiring board where the semiconductor device A10 is mounted, without requiring enlargement of the semiconductor device A10.

### Second Embodiment

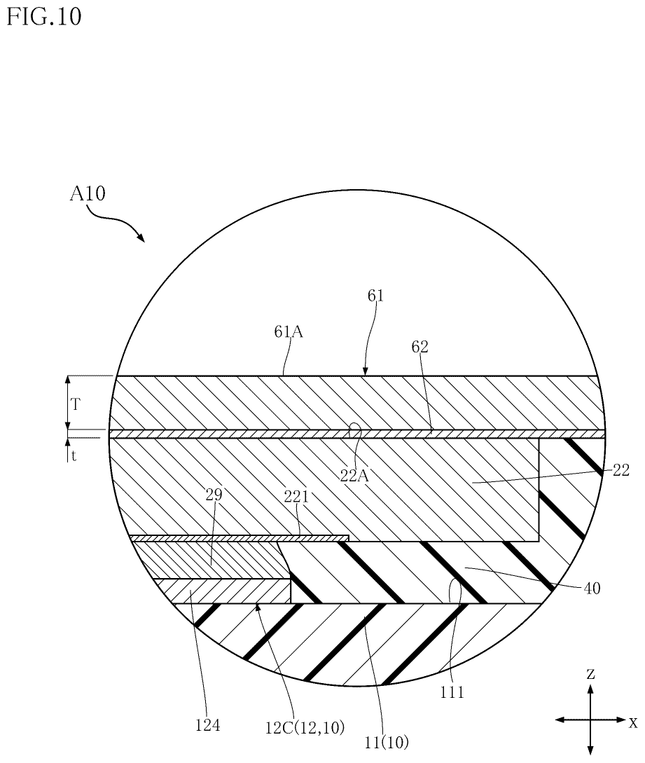

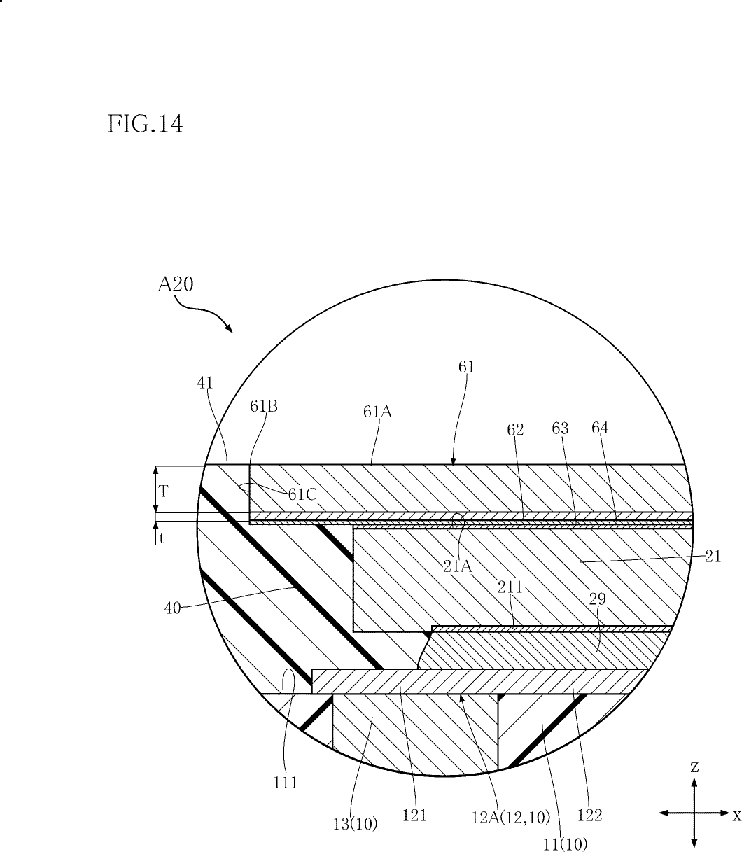

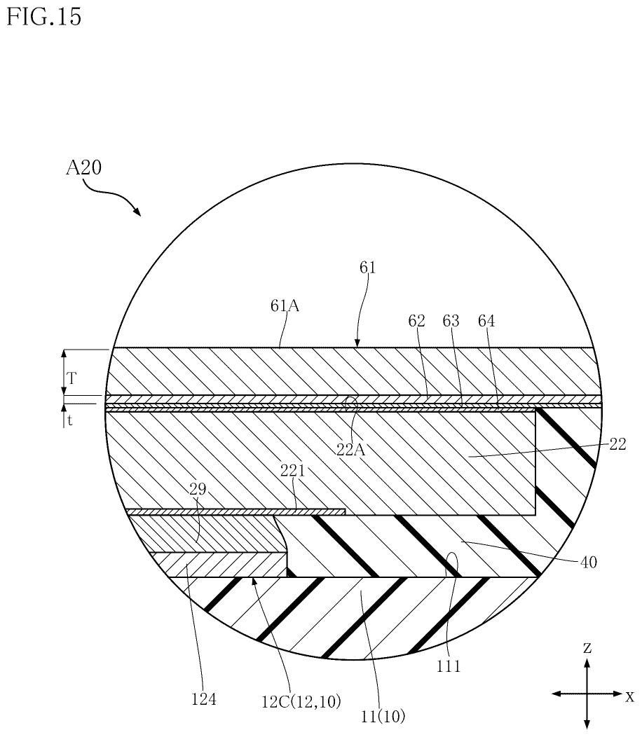

With reference to FIGS. 14 to 16, a semiconductor device A20 according to a second embodiment of the present disclosure is described. In these figures, elements identical or similar to those of the semiconductor device A10 described above are labeled with the same reference numerals, and redundant descriptions of such elements are omitted. The section shown in FIG. 14 is taken along the same position as the section of the semiconductor device A10 shown in FIG. 9. The section shown in FIG. 15 is taken along the same position as the section of the semiconductor device A10 shown in FIG. 10.

The semiconductor device A20 from differs the semiconductor device A10 in that it further includes a second intermediate layer 63 and two third intermediate layers 64.

As shown in FIGS. 14 and 15, the second intermediate layer 63 is located partly between the first obverse surface 21A of the first semiconductor element 21 and the first intermediate layer 62, and partly between the second obverse surface 22A of the second semiconductor element 22 and the first intermediate layer 62. The Vickers hardness of the second intermediate layer 63 is lower than that of the heat dissipating layer 61 and higher than that of the first intermediate layer 62. The composition of the second intermediate layer 63 includes silver (Ag). The second intermediate layer 63 is formed, for example, by sputtering a thin film of metal onto the first intermediate layer 62.

As shown in FIGS. 14 and 15, one of the two third intermediate layers 64 is located between the first obverse surface 21A of the first semiconductor element 21 and the second intermediate layer 63, and the other is located between the second obverse surface 22A of the second semiconductor element 22 and the second intermediate layer 63. The Vickers hardness of each third intermediate layer 64 is lower than that of the heat dissipating layer 61 and higher than that of the first intermediate layer 62. The composition of the two third intermediate layers 64 may be the same as the composition of the second intermediate layer 63. Hence, the composition of the third intermediate layers 64 may include silver. The third intermediate layers 64 are formed, for example, by sputtering a thin film of metal onto each of the first obverse surface 21A and the second obverse surface 22A.

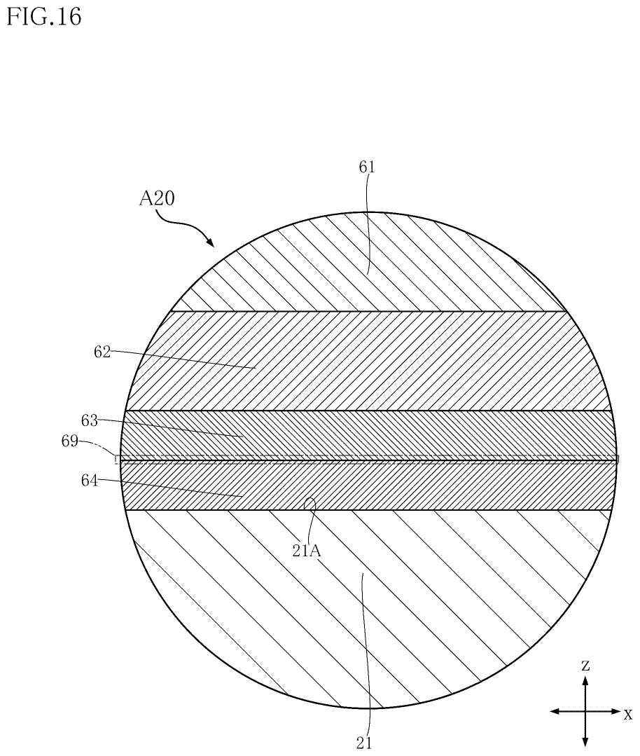

As shown in FIG. 16, the solid-phase diffusion bonding layer 69 is present between the first obverse surface 21A of the first semiconductor element 21 and the second intermediate layer 63. Although not illustrated in the figures, the solid-phase diffusion bonding layer 69 is also present between the second obverse surface 22A of the second semiconductor element 22 and the second intermediate layer 63. In the semiconductor device A20, the solid-phase diffusion bonding layer 69 is present between each third intermediate layer 64 and the second intermediate layer 63.

Next, the effects of the semiconductor device A20 will be described.

The semiconductor device A20 includes: the first semiconductor element 21 having the first obverse surface 21A facing away from the first and second electrodes 211 and 212 in the first direction z; the sealing resin 40 covering the first semiconductor element 21; and the heat dissipating layer 61 bonded to the first obverse surface 21A. The heat dissipating layer 61 has the heat dissipating surface 61A facing the same side as the first obverse surface 21A in the first direction z and exposed from the sealing resin 40 to the outside. The peripheral edge 61B of the heat dissipating surface 61A surrounds the first obverse surface 21A as viewed in the first direction z. The semiconductor device A20 can therefore improve its heat dissipation. Additionally, the semiconductor device A20 has a configuration in common with the semiconductor device A10 and thus achieves a corresponding effect as the semiconductor device A10.

The semiconductor device A20 further includes the second intermediate layer 63 that is located between the first obverse surface 21A of the first semiconductor element 21 and the first intermediate layer 62. The Vickers hardness of the second intermediate layer 63 is lower than that of the heat dissipating layer 61 and higher than that of the first intermediate layer 62. The solid-phase diffusion bonding layer 69 is present between the first obverse surface 21A and the second intermediate layer 63. This is beneficial for achieving a strong bond of the solid-phase diffusion bonding layer 69.

### Third Embodiment

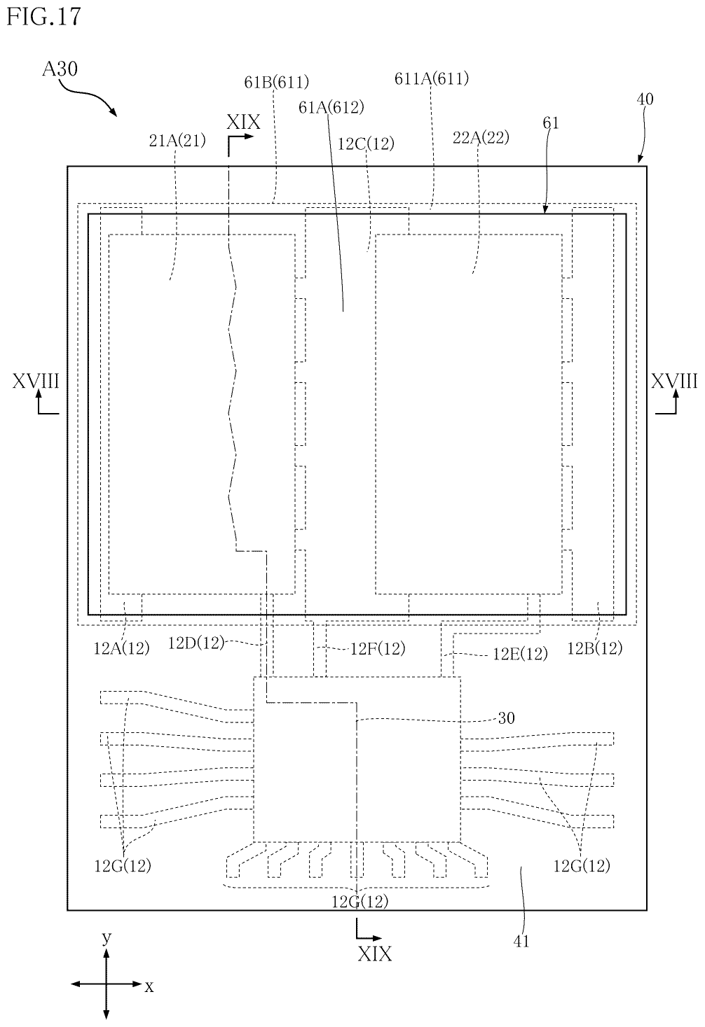

With reference to FIGS. 17 to 20, a semiconductor device A30 according to a third embodiment of the present disclosure is described. In these figures, elements identical or similar to those of the semiconductor device A10 described above are labeled with the same reference numerals, and redundant descriptions of such elements are omitted.

The semiconductor device A30 differs from the semiconductor device A10 in the configuration of the heat dissipating layer 61.

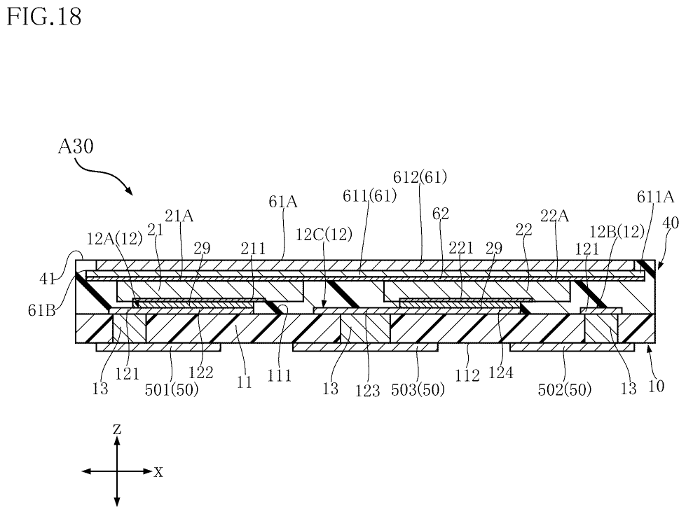

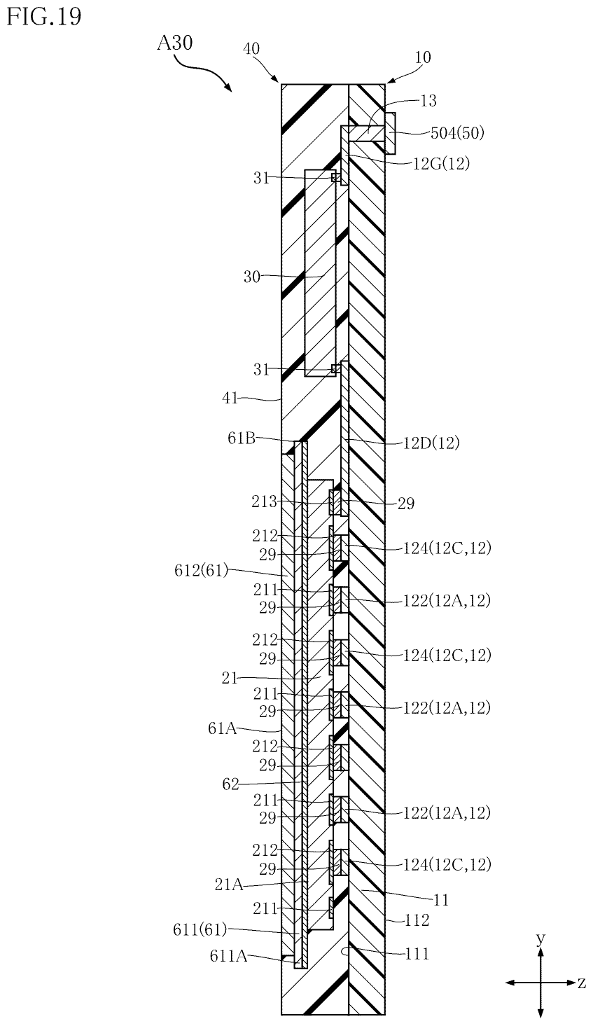

As shown in FIGS. 18 and 19, the heat dissipating layer 61 of this embodiment includes an insulating layer 611 and a first conductor layer 612. The first conduction layer 612 is adjacent to the insulating layer 611 in the first direction z. In the semiconductor device A30, the first conductor layer 612 is located on the side opposite the first semiconductor element 21 and the second semiconductor element 22 in the first direction z with respect to the insulating layer 611. The first conductor layer 612 includes the heat dissipating surface 61A. The insulating layer 611 is made of a material containing aluminum nitride (Al), for example. In one example, the first conductor layer 612 is made of the same material as that of the heat dissipating layer 61 of the semiconductor device A10. Preferably, the thermal conductivity of the insulating layer 611 is as close as possible to that of the first conductor layer 612.

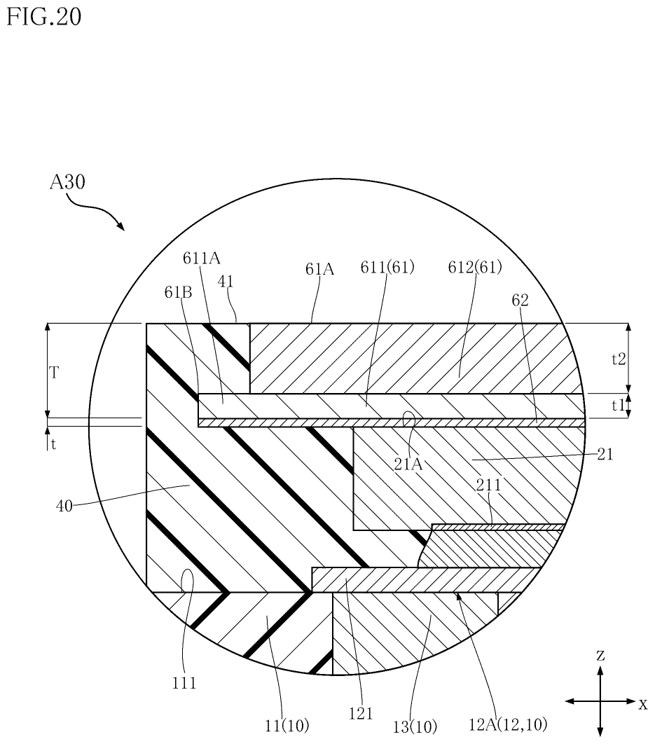

As shown in FIG. 20, the first intermediate layer 62 is stacked on the insulating layer 611. The dimension t2 of the first conductor layer 612 in the first direction z is larger than the dimension t1 of the insulating layer 611 in the first direction z.

As shown in FIGS. 17 to 20, the insulating layer 611 has a peripheral portion 611A that surrounds the heat dissipating surface 61A as viewed in the first direction z. In the semiconductor device A30, the peripheral portion 611A is sandwiched by the sealing resin 40 in the first direction z.

### First Variation of Third Embodiment

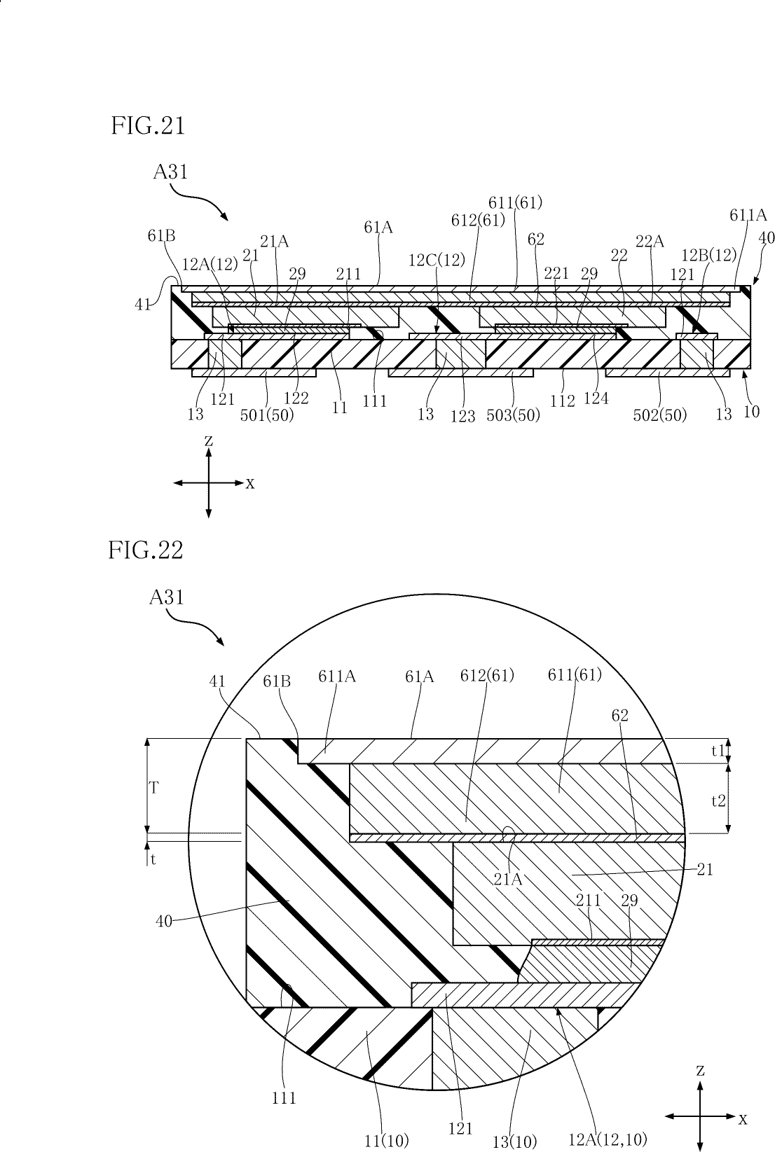

Next, with reference to FIGS. 21 and 22, the following describes a semiconductor device A31 that is a first variation of the semiconductor device A30. The section shown in FIG. 21 is taken along the same position as the section shown in FIG. 18.

As shown in FIG. 21, the semiconductor device A31 differs from the semiconductor device A30 in the configuration of the heat dissipating layer 61. The insulating layer 611 is located on the side opposite the first semiconductor element 21 and the second semiconductor element 22 in the first direction z with respect to the first conductor layer 612. The insulating layer 611 includes the heat dissipating surface 61A.

As shown in FIG. 22, the first intermediate layer 62 is stacked on the first conductor layer 612. In the semiconductor device A31, the peripheral portion 611A of the insulating layer 611, as well as the heat dissipating surface 61A, is exposed to the outside from the top surface 41 of the sealing resin 40.

### Second Variation of Third Embodiment

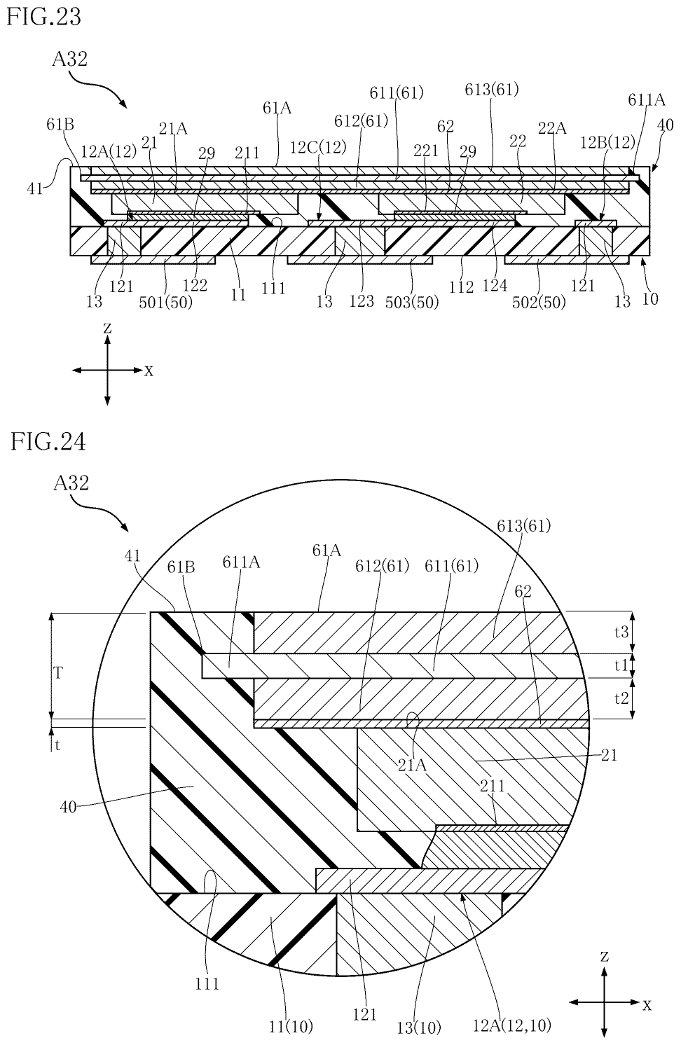

Next, with reference to FIGS. 23 and 24, the following describes a semiconductor device A32 that is a second variation of the semiconductor device A30. The section shown in FIG. 23 is taken along the same position as the section shown in FIG. 18.

As shown in FIG. 23, the semiconductor device A32 differs from the semiconductor device A30 in the configuration of the heat dissipating layer 61. The heat dissipating layer 61 further includes a second conductor layer 613. The insulating layer 611 is located on the side opposite the first semiconductor element 21 and the second semiconductor element 22 in the first direction z with respect to the first conductor layer 612. The second conductor layer 613 is located on the side opposite the first conductor layer 612 in the first direction z with respect to the insulating layer 611. The second conductor layer 613 includes the heat dissipating surface 61A. In one example, the second conductor layer 613 is made of the same material as that of the first conductor layer 612.

As shown in FIG. 24, the first intermediate layer 62 is stacked on the first conductor layer 612. The dimension t3 of the second conductor layer 613 in the first direction z is larger than the dimension t1 of the insulating layer 611 in the first direction z. In the semiconductor device A32, the dimension t3 of the second conductor layer 613 in the first direction z is the same as the dimension t2 of the first conductor layer 612 in the first direction z. In another example, the dimension t3 of the second conductor layer 613 in the first direction z may be different from the dimension t2 of the first conductor layer 612 in the first direction z. In the semiconductor device A32, the peripheral portion 611A of the insulating layer 611 is sandwiched by the sealing resin 40 in the first direction z.

Next, the effects of the semiconductor device A30 will be described.

The semiconductor device A30 includes: the first semiconductor element 21 having the first obverse surface 21A facing away from the first and second electrodes 211 and 212 in the first direction z; the sealing resin 40 covering the first semiconductor element 21; and the heat dissipating layer 61 bonded to the first obverse surface 21A. The heat dissipating layer 61 has the heat dissipating surface 61A facing the same side as the first obverse surface 21A in the first direction z and exposed from the sealing resin 40 to the outside. The peripheral edge 61B of the heat dissipating surface 61A surrounds the first obverse surface 21A as viewed in the first direction z. The semiconductor device A30 can therefore improve its heat dissipation. Additionally, the semiconductor device A30 has a configuration in common with the semiconductor device A10 and thus achieves the same effect as the semiconductor device A10.

In the semiconductor device A30, the heat dissipating layer 61 includes the insulating layer 611 and the first conductor layer 612 adjacent to the insulating layer 611 in the first direction z. This configuration ensures electrical insulation between the first obverse surface 21A of the first semiconductor element 21 and the external environment. Consequently, a heat sink can be attached to the heat dissipating surface 61A of the heat dissipating layer 61 without the need to provide an insulator between the heat dissipating surface 61A and the heat sink. This also helps to prevent or reduce the decrease in the dielectric strength of the semiconductor device A30 resulting from the presence of the heat dissipating layer 61.

In the semiconductor devices A30 and A32, the peripheral portion 611A of the insulating layer 611 is sandwiched by the sealing resin 40 in the first direction z. This configuration helps to prevent the detachment of the heat dissipating layer 61 from the sealing resin 40.

In the semiconductor device A32, the heat dissipating layer 61 includes the insulating layer 611, the first conductor layer 612, and the second conductor layer 613. This configuration makes it possible to achieve the heat dissipating layer 61 having a larger dimension T in the first direction z. Here, the dimension t3 of the second conductor layer 613 in the first direction z is larger than the dimension t2 of the first conductor layer 612 in the first direction z. With this configuration, the heat dissipating layer 61 can reduce the thermal resistance in the first direction z, while maintaining the electrical insulation between the first obverse surface 21A of the first semiconductor element 21 and the external environment.

### Fourth Embodiment

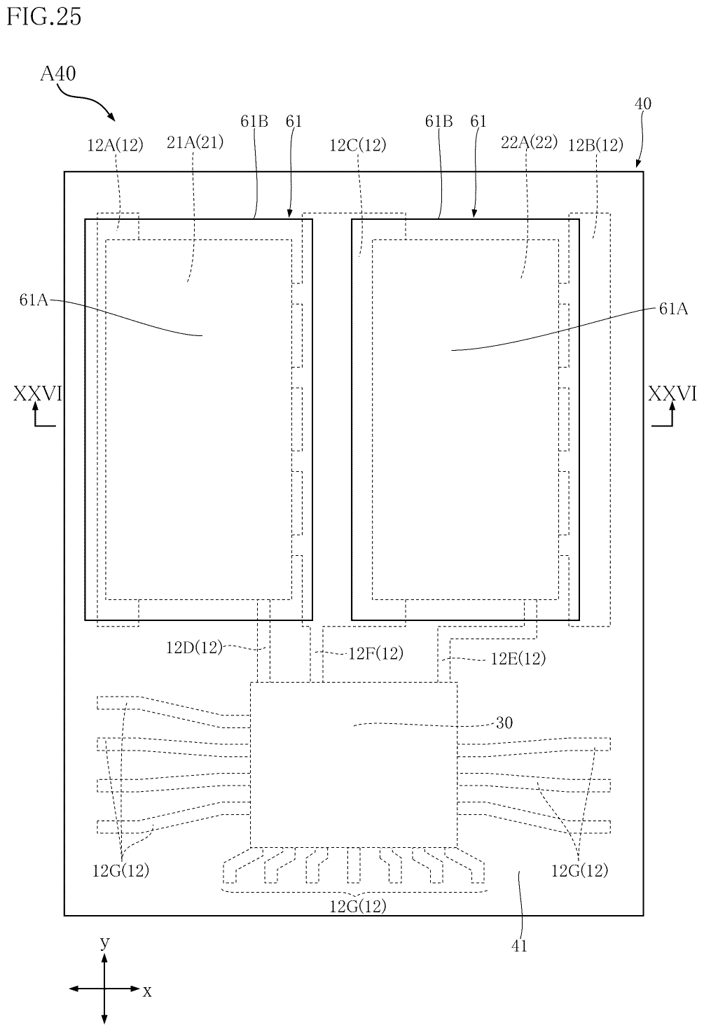

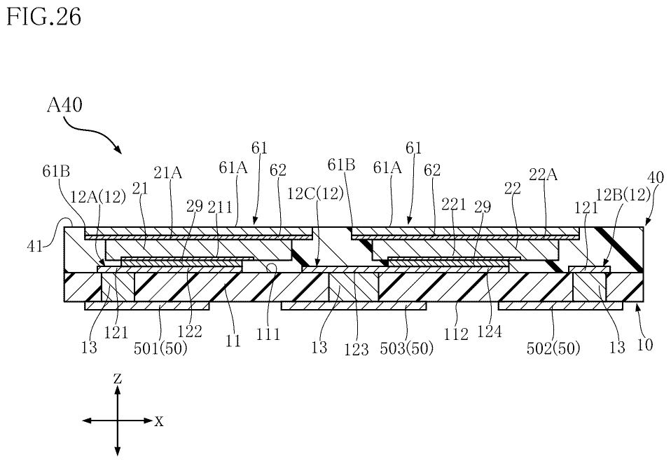

With reference to FIGS. 25 and 26, a semiconductor device A40 according to a fourth embodiment of the present disclosure is described. In these figures, elements identical or similar to those of the semiconductor device A10 described above are labeled with the same reference numerals, and redundant descriptions of such elements are omitted.

The semiconductor device differs from the A40 semiconductor device A10 in the configurations of the heat dissipating layer 61 and the first intermediate layer 62.

As shown in FIGS. 25 and 26, each of the heat dissipating layer 61 and the first intermediate layer 62 includes two regions that are spaced apart from each other in the second direction x. One region of the heat dissipating layer 61 is joined to the first obverse surface 21A of the first semiconductor element 21 via one region of the first intermediate layer 62. As viewed in the first direction z, that region of the heat dissipating layer 61 has a heat dissipating surface 61A, with its peripheral edge 61B surrounding the first obverse surface 21A. The other region of the heat dissipating layer 61 is joined to the second obverse surface 22A of the second semiconductor element 22 via the other region of the first intermediate layer 62. As viewed in the first direction z, that region of the heat dissipating layer 61 has a heat dissipating surface 61A, with its peripheral edge 61B surrounding the second obverse surface 22A.

Next, the effects of the semiconductor device A40 will be described.

The semiconductor device A40 includes: the first semiconductor element 21 having the first obverse surface 21A facing away from the first and second electrodes 211 and 212 in the first direction z; the sealing resin 40 covering the first semiconductor element 21; and the heat dissipating layer 61 bonded to the first obverse surface 21A. The heat dissipating layer 61 has the heat dissipating surface 61A facing the same side as the first obverse surface 21A in the first direction z and exposed from the sealing resin 40 to the outside. As viewed in the first direction z, the peripheral edge 61B of the heat dissipating surface 61A surrounds the first obverse surface 21A. The semiconductor device A40 can therefore improve its heat dissipation. Additionally, the semiconductor device A40 has a configuration in common with the semiconductor device A10 and thus achieves the same effect as the semiconductor device A10.

The present disclosure is not limited to the foregoing embodiments. Various modifications in design may be made freely in the specific structure of each part according to the present disclosure.

The present disclosure includes the embodiments described in the following clauses.

### Clause 1.

A semiconductor device comprising:
a first semiconductor element including a first obverse surface that faces in a first direction, and a first electrode and a second electrode that are located on a side opposite the first obverse surface in the first direction;
a sealing resin covering the first semiconductor element; and
a heat dissipating layer bonded to the first obverse surface,
wherein the heat dissipating layer includes a heat dissipating surface facing a same side as the first obverse surface in the first direction,
the heat dissipating surface is exposed from the sealing resin to outside, and
as viewed in the first direction, a peripheral edge of the heat dissipating surface surrounds the first obverse surface.

### Clause 2.

The semiconductor device according to Clause 1, further comprising a solid-phase diffusion bonding layer located between the first obverse surface and the heat dissipating layer.

### Clause 3.

The semiconductor device according to Clause 2, further comprising a first intermediate layer located between the first obverse surface and the heat dissipating layer,
wherein the solid-phase diffusion bonding layer is located between the first obverse surface and the first intermediate layer, and
a Vickers hardness of the first intermediate layer is lower than a Vickers hardness of the heat dissipating layer.

### Clause 4.

The semiconductor device according to Clause 3, wherein a dimension of the first intermediate layer in the first direction is smaller than a dimension of the heat dissipating layer in the first direction.

### Clause 5.

The semiconductor device according to Clause 4, further comprising a second intermediate layer located between the first obverse surface and the first intermediate layer,
wherein the solid-phase diffusion bonding layer is located between the first obverse surface and the second intermediate layer,
a Vickers hardness of the second intermediate layer is lower than the Vickers hardness of the heat dissipating layer, and
the Vickers hardness of the second intermediate layer is higher than the Vickers hardness of the first intermediate layer.

### Clause 6.

The semiconductor device according to Clause 2, wherein the heat dissipating layer includes an end surface facing in a direction orthogonal to the first direction, and
the end surface is inclined to be farther away from the first obverse surface as viewed in the first direction as a distance from the first obverse surface increases in the first direction.

### Clause 7.

The semiconductor device according to Clause 2, wherein the heat dissipating layer includes an insulating layer and a first conductor layer adjacent to the insulating layer in the first direction.

### Clause 8.

The semiconductor device according to Clause 7, wherein a dimension of the first conductor layer in the first direction is larger than a dimension of the insulating layer in the first direction.

### Clause 9.

The semiconductor device according to Clause 8, wherein the insulating layer includes a peripheral portion that surrounds the heat dissipating surface as viewed in the first direction.

### Clause 10.

The semiconductor device according to Clause 8 or 9, wherein the first conductor layer is located on a side opposite the first semiconductor element in the first direction with respect to the insulating layer, and
the first conductor layer includes the heat dissipating surface.

### Clause 11.

The semiconductor device according to Clause 8 or 9, wherein the insulating layer is located on a side opposite the first semiconductor element in the first direction with respect to the first conductor layer.

### Clause 12.

The semiconductor device according to Clause 11, wherein the heat dissipating layer includes a second conductor layer located on a side opposite the first conductor layer in the first direction with respect to the insulating layer, and
the second conductor layer includes the heat dissipating surface.

### Clause 13.

The semiconductor device according to Clause 12, wherein a dimension of the second conductor layer in the first direction is larger than the dimension of the insulating layer in the first direction.

### Clause 14.

The semiconductor device according to any one of Clauses 1 to 13, further comprising:
a substrate; and
a plurality of wirings disposed on the substrate,
wherein the first electrode and the second electrode are electrically bonded to the plurality of wirings.

### Clause 15.

The semiconductor device according to Clause 14, further comprising a second semiconductor element including a second obverse surface that faces a same side as the first obverse surface in the first direction and a third electrode and a fourth electrode that are located to face the plurality of wirings,
wherein the third electrode and the fourth electrode are electrically bonded to the plurality of wirings,
the heat dissipating layer is bonded to the second obverse surface,
the second semiconductor element is covered with the sealing resin, and
as viewed in the first direction, the peripheral edge of the heat dissipating surface surrounds the second obverse surface.

### Clause 16.

The semiconductor device according to Clause 15, further comprising an IC that is electrically connected to the plurality of wirings and drives the first semiconductor element and the second semiconductor element,
wherein the IC is covered with the sealing resin.

### Clause 17.

The semiconductor device according to any one of Clauses 14 to 16, further comprising a plurality of terminals electrically connected to the plurality of wirings,
wherein the plurality of terminals are located on a side opposite the plurality of wirings in the first direction with respect to the substrate.

### REFERENCE NUMERALS

A10, A20, A30, A40: semiconductor device
10: supporting member 11: substrate
111: mounting surface 112: reverse surface
12: wiring 12A: input wiring
12B: ground wiring 12C: output wiring
12D: first gate wiring 12E: second gate wiring
12F: potential wiring 12G: control wiring
121: first base portion 122: first extending portion
123: second base portion 124: second extending portion
13: connecting wiring 21: first semiconductor element
21A: first obverse surface
211: first electrode
212: second electrode 213: first gate electrode
22: second semiconductor element 22A: second obverse surface
221: third electrode 222: fourth electrode
223: second gate electrode 29: joint layer
30: IC 31: electrode
41: top surface 40: sealing resin
50: terminal 501: input terminal
502: ground terminal 503: output terminal
504: control terminal 61: heat dissipating layer
61A: heat dissipating surface 61B: peripheral edge
61C: end surface 611: insulating layer
611A: peripheral portion 612: first conductor layer
613: second conductor layer 62: first intermediate layer
63: second intermediate layer 64: third intermediate layer
69: solid-phase diffusion bonding layer z: first direction
x: second direction y: third direction

1. A semiconductor device comprising:
a first semiconductor element including a first obverse surface that faces in a first direction, and a first electrode and a second electrode that are located on a side opposite the first obverse surface in the first direction;
a sealing resin covering the first semiconductor element; and
a heat dissipating layer bonded to the first obverse surface,
wherein the heat dissipating layer includes a heat dissipating surface facing a same side as the first obverse surface in the first direction,
the heat dissipating surface is exposed from the sealing resin to outside, and
as viewed in the first direction, a peripheral edge of the heat dissipating surface surrounds the first obverse surface.

2. The semiconductor device according to claim 1, further comprising a solid-phase diffusion bonding layer located between the first obverse surface and the heat dissipating layer.

3. The semiconductor device according to claim 2, further comprising a first intermediate layer located between the first obverse surface and the heat dissipating layer,
wherein the solid-phase diffusion bonding layer is located between the first obverse surface and the first intermediate layer, and
a Vickers hardness of the first intermediate layer is lower than a Vickers hardness of the heat dissipating layer.

4. The semiconductor device according to claim 3, wherein a dimension of the first intermediate layer in the first direction is smaller than a dimension of the heat dissipating layer in the first direction.

5. The semiconductor device according to claim 4, further comprising a second intermediate layer located between the first obverse surface and the first intermediate layer,
wherein the solid-phase diffusion bonding layer is located between the first obverse surface and the second intermediate layer,
a Vickers hardness of the second intermediate layer is lower than the Vickers hardness of the heat dissipating layer, and
the Vickers hardness of the second intermediate layer is higher than the Vickers hardness of the first intermediate layer.

6. The semiconductor device according to claim 2, wherein the heat dissipating layer includes an end surface facing in a direction orthogonal to the first direction, and
the end surface is inclined to be farther away from the first obverse surface as viewed in the first direction as a distance from the first obverse surface increases in the first direction.

7. The semiconductor device according to claim 2, wherein the heat dissipating layer includes an insulating layer and a first conductor layer adjacent to the insulating layer in the first direction.

8. The semiconductor device according to claim 7, wherein a dimension of the first conductor layer in the first direction is larger than a dimension of the insulating layer in the first direction.

9. The semiconductor device according to claim 8, wherein the insulating layer includes a peripheral portion that surrounds the heat dissipating surface as viewed in the first direction.

10. The semiconductor device according to claim 8, wherein the first conductor layer is located on a side opposite the first semiconductor element in the first direction with respect to the insulating layer, and
the first conductor layer includes the heat dissipating surface.

11. The semiconductor device according to claim 8, wherein the insulating layer is located on a side opposite the first semiconductor element in the first direction with respect to the first conductor layer.

12. The semiconductor device according to claim 11, wherein the heat dissipating layer includes a second conductor layer located on a side opposite the first conductor layer in the first direction with respect to the insulating layer, and
the second conductor layer includes the heat dissipating surface.

13. The semiconductor device according to claim 12, wherein a dimension of the second conductor layer in the first direction is larger than the dimension of the insulating layer in the first direction.

14. The semiconductor device according to claim 1, further comprising:
a substrate; and
a plurality of wirings disposed on the substrate,
wherein the first electrode and the second electrode are electrically bonded to the plurality of wirings.

15. The semiconductor device according to claim 14, further comprising a second semiconductor element including a second obverse surface that faces a same side as the first obverse surface in the first direction and a third electrode and a fourth electrode that are located to face the plurality of wirings,
wherein the third electrode and the fourth electrode are electrically bonded to the plurality of wirings,
the heat dissipating layer is bonded to the second obverse surface,
the second semiconductor element is covered with the sealing resin, and
as viewed in the first direction, the peripheral edge of the heat dissipating surface surrounds the second obverse surface.

16. The semiconductor device according to claim 15, further comprising an IC that is electrically connected to the plurality of wirings and drives the first semiconductor element and the second semiconductor element,
wherein the IC is covered with the sealing resin.

17. The semiconductor device according to claim 14, further comprising a plurality of terminals electrically connected to the plurality of wirings,
wherein the plurality of terminals are located on a side opposite the plurality of wirings in the first direction with respect to the substrate.
